(19) United States
(12) Patent Application Publication
(10) Pub. No.: US 2013/0306357 A1
(43) Pub. Date: Nov. 21, 2013

(54) EPOXY RESIN COMPOSITION, AND PREPREG AND PRINTED CIRCUIT BOARD USNG THE SAME

(71) Applicant: Taiwan Union Technology Corporation, Chupei City (TW)

(72) Inventors: Hsuan Hao HSU, Hsinchu Hsien (TW); Jiun Jie HUANG, Hsinchu Hsien (TW); Mei Ling CHU, Hsinchu Hsien (TW); Hsien Te CHEN, Hsinchu Hsien (TW)

(73) Assignee: Taiwan Union Technology Corporation, Chupei City (TW)

(21) Appl. No.: 13/952,006

(22) Filed: Jul. 26, 2013

Related U.S. Application Data
(62) Division of application No. 12/917,202, filed on Nov. 1, 2010.

(30) Foreign Application Priority Data
Aug. 2, 2010 (TW) 099125621

(51) Int. Cl. C09D 163/00; H05K 3/00

(52) U.S. Cl. CPC C09D 163/00; H05K 3/0064
USPC 174/250; 216/20; 523/438

(57) ABSTRACT

Disclosed is an epoxy resin composition for printed circuit board, which includes (A) an epoxy resin comprising a dicyclopentadiene type epoxy resin; (B) a copolymer of styrene and maleic anhydride as a curing agent; (C) a curing accelerator; (D) an optional silane dispersing agent; (E) an optional phosphorous-containing flame retardant; (F) an optional toughening agent; and (G) an optional inorganic filler.

### CROSS REFERENCE TO RELATED APPLICATIONS

This application is a division of U.S. patent application Ser. No. 12/917,202, filed on Nov. 1, 2010, which is incorporated herewith by reference.

### BACKGROUND OF THE INVENTION

1. Field of the Invention

The present invention relates to an epoxy resin composition, a prepreg containing the epoxy resin composition, and a printed circuit board (PCB) which is formed by using the prepregs,.

2. The Prior Arts

The printed circuit boards are typically manufactured by using the prepregs. For manufacturing a prepreg, in general, a substrate was impregnated with a varnish prepared by dissolving a thermosetting resin, such as epoxy resin, in a solvent, followed by curing the resin to the “B-stage,” and such impregnated substrate is commonly referred to as prepreg. For manufacturing a printed circuit board, in general, it involves laminating a particular number of layers of prepregs, and placing a metal foil additionally on at least one outermost layer, and forming a particular circuit pattern on the surface of the metal-clad laminate by etching the metal foil formed thereon.

Recently, the demand for downsizing the printed circuit boards on which electronic components are mounted is increasingly rising. Accordingly, it is required that the wire width is reduced, the diameter of the through-hole is reduced, and the plating thickness is reduced. However, the reduction of plating thickness can cause the plating to crack or blister when a heat shock is applied to the plating. Thus, the printed circuit boards are required to be highly heat-resistant. On the other hand, it is desired to lower the dielectric constant of a base material for the printed circuit boards to meet the speed up of the signal transmission speed required for high-speed information processing, and also it is desired to use a base material with a low dielectric dissipation factor (dielectric loss) in order to lower the loss of transmission.

Poly(phenylene oxide) resins (PPO) are suitable as a base material for the printed circuit boards used in the electronic devices that utilize broadband, owing to their favorable high frequency characteristics, for example in dielectric constant and dielectric loss. However, poly(phenylene oxide) resins are inadequate in achieving high heat resistance and dimensional stability.

TW patent publication No. 216439 disclosed an epoxy resin composition including a dicyclopentadiene type epoxy resin which had a less polar, hydrophobic bicyclic hydrocarbon group and thus had superior dielectric characteristics and moisture resistance, and however, on the other hand, dicyandiamide (DICY) was used as an epoxy resin curing agent in this patent. Although dicyandiamide can improve the properties of the laminate for PCB such as tenacity and processibility, it has the drawback of poor solubility to the commonly used solvents so that dicyanodiamide has a tendency to crystallize in the resin and the prepreg made therefrom.

TW patent publication No. 455613 disclosed the use of a copolymer of styrene and maleic anhydride (SMA) as a curing agent for epoxy resin in order to increase the glass transition temperature of thermosetting epoxy laminate. However, the resin compositions, in which the epoxy resin is cross-linked with a copolymer of styrene and maleic anhydride, have the drawback of being too brittle to be processed as prepregs. For instance, it proves impossible to cut up such prepregs without a portion of the resin blowing about in the form of a large quantity of dry dust.

Accordingly, there still exists a need for investigation of a new epoxy resin composition that shows excellent dielectric characteristics (i.e. low dielectric constant and low dissipation factor) as well as improved heat resistance and processibility, and thus being useful as a base material for the production of a copper clad laminate for high speed signal transfer.

### SUMMARY OF THE INVENTION

Accordingly, the objective of the present invention is to provide an epoxy resin composition having superior dielectric characteristics with low dielectric constant and dissipation factor, and having improved glass transition temperature, heat resistance, breaking tenacity and processibility, and also to provide a prepreg and a printed circuit board for high speed signal transfer, which are prepared from such an epoxy resin composition.

To achieve the foregoing objective, the present invention provides an epoxy resin composition comprising:

(A) an epoxy resin comprising a dicyclopentadiene type epoxy resin represented by the following general formula (I):

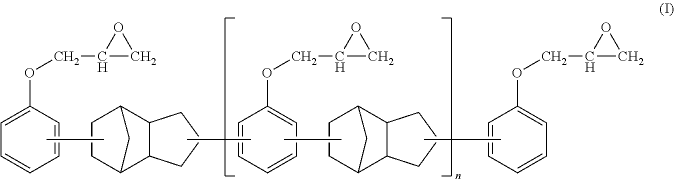

where n is an integer of 0 to 10; and
(B) 30 to 80 parts by weight of a copolymer of styrene and maleic anhydride as a curing agent, based on 100 parts by weight of the epoxy resin, and the copolymer of styrene and maleic anhydride is represented by the following general formula (II):

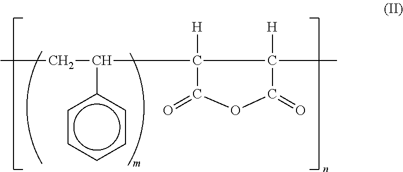

where m is an integer of 1 to 6, and n is an integer of 2 to 12.

The epoxy resin composition of the present invention may further include preferably a curing accelerator additionally.

The epoxy resin composition of the present invention may further include preferably a dispersing agent additionally.

The epoxy resin composition of the present invention may further include preferably a phosphorous-containing flame retardant additionally.

The epoxy resin composition of the present invention may further include preferably a toughening agent additionally.

The epoxy resin composition of the present invention may further include optionally an inorganic filler.

The present invention further provides a prepreg produced by impregnating a reinforcing material with the epoxy resin composition of the present invention to form an impregnated substrate, and drying the impregnated substrate to a semi-cured state.

The present invention yet further provides a PCB produced by laminating a particular number of the prepregs of the present invention to form a prepreg laminate, placing a metal foil on at least one outermost layer of the prepreg laminate and heat pressure-molding the prepreg laminate to form a metal-clad laminate, and forming a particular circuit pattern on the surface of the metal foil on the metal-clad laminate.

The objective, characteristics, aspects, and advantages of the present invention will become more evident in the following detailed description.

### DETAILED DESCRIPTION OF THE PREFERRED EMBODIMENT

In one preferred embodiment of the present invention, the epoxy resin composition for the printed circuit board comprises:

(A) an epoxy resin comprising 70 to 100, parts by weight of dicyclopentadiene type epoxy resin, and 0 to 30 parts by weight of bisphenol type epoxy resin, wherein the dicyclopentadiene type epoxy resin is represented by the following general formula (I):

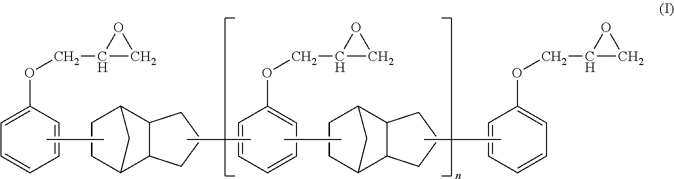

where n is an integer of 0 to 10;
(B) 30 to 80 parts by weight of a copolymer of styrene and maleic anhydride represented by the following general formula (II) as a curing agent:

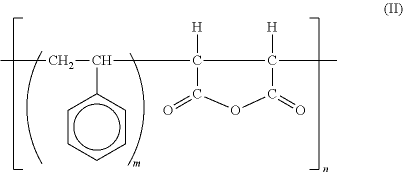

where m is an integer of 1 to 6, and n is an integer of 2 to 12;
(C) 0.1 to 1 parts by weight of a curing accelerator; (D) 0 to 1 parts by weight of a silane dispersing agent; (E) 0 to 25 parts by weight of a phosphorous-containing flame retardant; (F) 0 to 5 parts by weight of a toughening agent; and (G) 0 to 80 parts by weight of an inorganic filler. The parts by weight of components (B), (C), (D), (E), (F), and (G) are based on 100 parts by weight of the total weight of the epoxy resin.

The epoxy resin (A) used in the epoxy resin composition of the present invention comprises a dicyclopentadiene type epoxy resin and an optional bisphenol type epoxy resin. The dicyclopentadiene type epoxy resin used in the epoxy resin composition of the present invention has an epoxy equivalence of 200 to 300 g/eq, and has an average functionality of from 2 to 10, and the average functionality is the average number of functional groups per monomer. The bisphenol type epoxy resin used in the epoxy resin composition of the present invention has an epoxy equivalence of 200 to 390 g/eq. Examples of bisphenol type epoxy resin include, but are not limited to, bisphenol A epoxy resin, bisphenol F epoxy resin, bisphenol S epoxy resin, and mixtures thereof. The epoxy resin used in the epoxy resin composition of the present invention comprises 70 to 100 parts by weight of dicyclopentadiene type epoxy resin and 0 to 30 parts by weight of bisphenol epoxy resin, based on 100 parts by weight of the total weight of the epoxy resin.

The curing agent (B) used in the epoxy resin composition of the present invention comprises a copolymer of styrene and maleic anhydride (SMA). The copolymer of styrene and maleic anhydride has a molecular weight in the range of about 1400 to about 50,000 and an anhydride content of more than 15% by weight. The SMA can be selected from one SMA or a mixture of SMA's having a styrene:maleic anhydride ratio of 1:1 to 4:1, and a molecular weight of about 1400 to about 2,000. The curing agent is present in the epoxy resin composition of the present invention in an amount from 30 to 80 parts by weight, and preferably 40 parts by weight, based on 100 parts by weight of the total weight of the epoxy resin.

The curing accelerator (C) used in the epoxy resin composition of the present invention can be any compound that is used for accelerating the curing of an epoxy resin. Examples of the curing accelerator used in the present invention include, but are not limited to, tetrabutylphosphonium acetate, 2-methylimidazole, 2-ethyl-4-methylimidazole, and 2-phenylimidazole. These curing accelerators can be used singly or in combination of two or more of them. The preferred curing accelerator is tetrabutylphosphonium acetate. The amount of curing accelerator used is dependent on the type of epoxy resin, the type of curing agent, and the type of curing accelerator. The curing accelerator is present in the epoxy resin composition of the present invention in an amount from about 0.1 to 1 parts by weight, and preferably 0.5 parts by weight, based on 100 parts by weight of the total weight of the epoxy resin.

The optional silane dispersing agent (D) used in the epoxy resin composition of the present invention is used to facilitate and stabilize the dispersion of solid compounding materials such as fillers in a polymeric matrix (or a liquid resin). The silane dispersing agent is present in the epoxy resin composition of the present invention in an amount between 0.1 and 1 parts by weight, based on 100 parts by weight of the total weight of the epoxy resin.

The optional phosphorous-containing flame retardant (E) used in the epoxy resin composition of the present invention is utilized to endow flame retardancy to the epoxy resin composition. Examples of the phosphorous-containing flame retardant used in the epoxy resin composition of the present invention include, but are not limited to, poly (1,3-phenylene methylphosphonate); DOPO-BNE which is obtained by reacting 9,10-dihydro-9-oxa-10-phosphaphenanthrene-10-oxide (DOPO) with bisphenol A novolac epoxy resin (BNE); and polyphosphazenes which has the following structure:

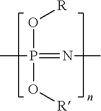

where R, and R′ are alkyl groups and may be the same or different. These above-mentioned phosphorous-containing flame retardants can be used singly or in combination of two or more of them. The phosphorous-containing flame retardant is present in the epoxy resin composition of the present invention in an amount between 0 and 25 parts by weight, based on 100 parts by weight of the total weight of the epoxy resin.

The toughening agent (F) is added to the epoxy resin composition of the present invention to improve the breaking tenacity of the resulting laminates. Examples of the toughening agent used in the present invention include, but are not limited to, carboxyl-terminated butadiene acrylonitrile rubber (CTBN) having viscosity of 300,000 to 800,000 cps and having the number-average molecular weight of larger than 4,000, and methyl methacrylate/butadiene/styrene copolymer. The preferred toughener is a carboxyl-terminated butadiene acrylonitrile rubber. The toughening agent is present in the epoxy resin composition of the present invention in an amount between 0 and 5 parts by weight, and preferably 2 parts by weight, based on 100 parts by weight of the total weight of the epoxy resin.

The optional inorganic filler (D) used in the epoxy resin composition of the present invention serves to impart additional heat resistance and humidity resistance to the epoxy resin composition. Examples of the inorganic filler used in the present invention include, but are not limited to, fused silica, crystalline silica, silicon carbide; silicon nitride, boron nitride, calcium carbonate, barium sulfate, calcium sulfate, mica, talc, clay, alumina, magnesium oxide, zirconium oxide, aluminum hydroxide, magnesium hydroxide, calcium silicate, aluminum silicate, lithium aluminum silicate, zirconium silicate, and molybdenum disulfide. These inorganic fillers can be used singly or in combination of two or more of them. The preferred inorganic fillers include talc and aluminum hydroxide. If the inorganic filler exists in the epoxy resin composition of the present invention, it is present in an amount between 0 and 80 parts by weight, based on 100 parts by weight of the total weight of the epoxy resin.

One or more solvents can be used for preparing the epoxy resin composition varnish in the present invention in order to provide resin solubility, and control resin viscosity. Examples of the solvents used in the present invention include, but are not limited to, acetone, methylethylketone, propylene glycol methyl ether, cyclohexanone, propylene glycol methyl ether acetate. These solvents can be used singly or in combination of two or more of them. The preferred solvents include methylethylketone, and propylene glycol methyl ether. The solvent is present in the epoxy resin composition of the present invention in an amount from about 60 to 90 parts by weight, based on 100 parts by weight of the total weight of the epoxy resin.

In one embodiment, the epoxy resin composition of the present invention can be prepared by blending the above-mentioned components (A), (B), (C), (D), (E), (F) and (G), and agitating the mixture uniformly, for example, in a mixer or blender.

The epoxy resin composition varnish of the present invention is prepared by dissolving or dispersing the obtained epoxy resin composition in a solvent.

A reinforcing material is impregnated with the resin varnish to form an impregnated substrate, and then the impregnated substrate is heated in a dryer at 150 to 180° C. for 2 to 10 minutes to give a prepreg in a semi-cured state (B-stage). Examples of the reinforcing material used in the present invention include, but are not limited to, glass fiber cloth, glass paper and glass mat, and also, kraft paper and linter paper.

A metal-clad laminate is prepared by laminating a particular number of the prepregs thus obtained, placing a metal foil additionally on at least one outermost layer and molding the composite under heat and pressure. As for the heat pressure-molding condition, the temperature is 160 to 190° C., the molding pressure is 10 to 30 kg/cm², and the molding time is 30 to 120 minutes. Then, a metal-clad laminate used for production of printed circuit boards is formed under such heat and pressure conditions. Examples of the metal foils used in the present invention include, but are not limited to, copper foil, aluminum foil, and stainless steel foil.

A circuit pattern formed on the surface of the metal-clad laminate is obtained by leaving circuit pattern-forming regions and removing the other regions thereof by using the subtractive process, otherwise known as the etching process. In this way, a printed circuit board carrying a circuit on the surface is obtained.

Hereinafter, the present invention will be described in more detail with reference to Examples. It should be understood that the present invention is not restricted at all by these Examples.

### Preparation of Epoxy Resin Composition Varnishes

### Example 1

100 parts by weight of dicyclopentadiene type epoxy resin (HP-7200H, manufactured by Dainippon Ink and Chemicals Inc., epoxy equivalence of 279 g/eq), 40 parts by weight of a copolymer of styrene and maleic anhydride (SMA EF40, manufactured by Sartomer Co., anhydride equivalence of 393 g/eq, molecular weight of 11,000, and styrene:maleic anhydride ratio of 4:1), 0.5 parts by weight of tetrabutylphosphonium acetate (manufactured by Deepwater, Inc.), 0.5 parts by weight of silane dispersing agent (Z-6032, Dow Corning Co.), 22 parts by weight of polyphosphazenes (SPB-100, manufactured by Otsuka Chemical Co.), 15 parts by weight of DOPO-BNE which is obtained by reacting 9,10-dihydro-9-oxa-10-phosphaphenanthrene-10-oxide with bisphenol A novolac epoxy resin (XZ-92741, manufactured by Dow Chemical Co.), 2 parts by weight of carboxyl-terminated butadiene acrylonitrile rubber (EPON 58005, manufactured by Hexion Specialty Chemicals), and 60 parts by weight of talc were mixed together by a mixer at room temperature for 60 minutes, and then the obtained mixture was dissolved in 80 parts by weight of methyl ethyl ketone, followed by stirring in a disperser at room temperature for 120 minutes to give the epoxy resin composition varnish.

### Example 2

100 parts by weight of dicyclopentadiene type epoxy resin (HP-7200H, manufactured by Dainippon Ink and Chemicals Inc., epoxy equivalence of 279 g/eq), 30 parts by weight of a copolymer of styrene and maleic anhydride (SMA EF40, manufactured by Sartomer Co., anhydride equivalence of 393 g/eq, molecular weight of 11,000, and styrene:maleic anhydride ratio of 4:1), 0.5 parts by weight of tetrabutylphosphonium acetate (manufactured by Deepwater Chemicals, Inc.), 0.5 parts by weight of silane dispersing agent (Z-6032, Dow Corning Co), 22 parts by weight of polyphosphazenes (SPB-100, manufactured by Otsuka Chemical Co.), 15 parts by weight of DOPO-BNE (XZ-92741, manufactured by Dow Chemical Co.), 2 parts by weight of carboxyl-terminated butadiene acrylonitrile rubber (EPON 58005, manufactured by Hexion Specialty Chemicals), and 60 parts by weight of talc were mixed together by a mixer at room temperature for 60 minutes, and then the obtained mixture was dissolved in 80 parts by weight of methylethylketone, followed by stirring in a disperser at room temperature for 120 minutes to give the epoxy resin composition varnish.

### Example 3

100 parts by weight of dicyclopentadiene type epoxy resin (HP-7200H, manufactured by Dainippon Ink and Chemicals Inc., epoxy equivalence of 279 g/eq), 80 parts by weight of a copolymer of styrene and maleic anhydride (SMA EF40, manufactured by Sartomer Co., anhydride equivalence of 393 g/eq, molecular weight of 11,000, and styrene:maleic anhydride ratio of 4:1), 0.5 parts by weight of tetrabutylphosphonium acetate (manufactured by Deepwater Chemicals, Inc.), 0.5 parts by weight of silane dispersing agent (Z-6032, Dow Corning Co.), 22 parts by weight of polyphosphazenes (SPB-100, manufactured by Otsuka Chemical Co.), 15 parts by weight of DOPO-BNE (XZ-92741, manufactured by Dow Chemical Co.), 2 parts by weight of carboxyl-terminated butadiene acrylonitrile rubber (EPON 58005, manufactured by Hexion Specialty Chemicals), and 60 parts by weight of talc were mixed together by a mixer at room temperature for 60 minutes, and then the obtained mixture was dissolved in 80 parts by weight of methylethylketone, followed by stirring in a disperser at room temperature for 120 minutes to give the epoxy resin composition varnish.

### Example 4

80 parts by weight of dicyclopentadiene type epoxy resin (HP-7200H, manufactured by Dainippon Ink and Chemicals Inc., epoxy equivalence of 279 g/eq), 20 parts by weight of bisphenol A novolac epoxy resin (KEB-3165, manufactured by Kolon Chemical Co., epoxy equivalence of 213 g/eq), 40 parts by weight of a copolymer of styrene and maleic anhydride (SMA EF40, manufactured by Sartomer Co., anhydride equivalence of 393 g/eq, molecular weight of 11,000, and styrene:maleic anhydride ratio of 4:1), 0.5 parts by weight of tetrabutylphosphonium acetate (manufactured by Deepwater Chemicals, Inc.), 0.5 parts by weight of silane dispersing agent (Z-6032, Dow Corning Co.), 22 parts by weight of polyphosphazenes (SPB-100, manufactured by Otsuka Chemical Co.), 15 parts by weight of DOPO-BNE (XZ-92741, manufactured by Dow Chemical Co.), 2 parts by weight of carboxyl-terminated butadiene acrylonitrile rubber (EPON 58005, manufactured by Hexion Specialty Chemicals), and 60 parts by weight of talc were mixed together by a mixer at room temperature for 60 minutes, and then the obtained mixture was dissolved in 80 parts by weight of methylethylketone, followed by stirring in a disperser at room temperature for 120 minutes to give the epoxy resin composition varnish.

### Example 5

100 parts by weight of dicyclopentadiene type epoxy resin (HP-7200H, manufactured by Dainippon Ink and Chemicals Inc., epoxy equivalence of 279 g/eq), 40 parts by weight of a copolymer of styrene and maleic anhydride (SMA EF40, manufactured by Sartomer Co., anhydride equivalence of 393 g/eq, molecular weight of 11,000, and styrene:maleic anhydride ratio of 4:1), 0.5 parts by weight of tetrabutylphosphonium acetate (manufactured by Deepwater Chemicals, Inc.), 0.5 parts by weight of silane dispersing agent (Z-6032, Dow Corning Co.), 2 parts by weight of carboxyl-terminated butadiene acrylonitrile rubber (EPON 58005, manufactured by Hexion Specialty Chemicals), and 60 parts by weight of talc were mixed together by a mixer at room temperature for 60 minutes, and then the obtained mixture was dissolved in 80 parts by weight of methylethylketone, followed by stirring in a disperser at room temperature for 120 minutes to give the epoxy resin composition varnish.

### Example 6

100 parts by weight of dicyclopentadiene type epoxy resin (HP-7200H, manufactured by Dainippon Ink and Chemicals Inc., epoxy equivalence of 279 g/eq), 40 parts by weight of a copolymer of styrene and maleic anhydride (SMA EF40, manufactured by Sartomer Co., anhydride equivalence of 393 g/eq, molecular weight of 11,000, and styrene:maleic anhydride ratio of 4:1), 0.5 parts by weight of tetrabutylphosphonium acetate (manufactured by Deepwater Chemicals, Inc.), 22 parts by weight of polyphosphazenes (SPB-100, manufactured by Otsuka Chemical Co.), 15 parts by weight of DOPO-BNE (XZ-92741, manufactured by Dow Chemical Co.), and 2 parts by weight of carboxyl-terminated butadiene acrylonitrile rubber (EPON 58005, manufactured by Hexion Specialty Chemicals) were mixed together by a mixer at room temperature for 60 minutes, and then the obtained mixture was dissolved in 80 parts by weight of methylethylketone, followed by stirring in a disperser at room temperature for 120 minutes to give the epoxy resin composition varnish.

### Example 7

70 parts by weight of dicyclopentadiene type epoxy resin (HP-7200H, manufactured by Dainippon Ink and Chemicals Inc., epoxy equivalence of 279 g/eq), 30 parts by weight of bisphenol A novolac epoxy resin (KEB-3165, manufactured by Kolon Chemical Co., epoxy equivalence of 213 g/eq), 30 parts by weight of a copolymer of styrene and maleic anhydride (SMA EF40, manufactured by Sartomer Co., anhydride equivalence of 393 g/eq, molecular weight of 11,000, and styrene:maleic anhydride ratio of 4:1), 0.5 parts by weight of tetrabutylphosphonium acetate (manufactured by Deepwater Chemicals, Inc.), 0.5 parts by weight of silane dispersing agent (Z-6032, Dow Corning Co.), 22 parts by weight of polyphosphazenes (SPB-100, manufactured by Otsuka Chemical Co.), 15 parts by weight of DOPO-BNE (XZ-92741, manufactured by Dow Chemical Co.), and 60 parts by weight of talc were mixed together by a mixer at room temperature for 60 minutes, and then the obtained mixture was dissolved in 80 parts by weight of methylethylketone, followed by stirring in a disperser at room temperature for 120 minutes to give the epoxy resin composition varnish.

### Comparative Example 1

An epoxy resin composition varnish was prepared in substantially the same manner as in Example 1, except that carboxyl-terminated butadiene acrylonitrile rubber was not used.

### <Preparation of Prepregs>

The 7628 (R/C: 43%) glass fiber cloths (product of Nitto Boseki Co., Ltd) were respectively impregnated with the resin varnish obtained in Examples 1 to 7 and Comparative Example 1 at room temperature, and followed by heating the impregnated glass fiber cloths at approximately 180° C. for 2 to 10 minutes to remove the solvent in the resin varnish (here, the resulting epoxy resin compositions were semi-cured) to obtain the prepregs of Examples 1 to 7 and Comparative Example 1.

### <Preparation of Printed Circuit Boards>

Four prepregs (300 mm×510 mm) of Example 1 were held and laminated between two copper foils (thickness: 1 oz, product of Nikko Gould Foil Co., Ltd.), to give a laminate. The laminate was then molded under the heating/pressurization condition of the temperature of 180° C. (the programmed heating rate of 2.0° C./minutes) and the pressure of 15 kg/cm² (an initial pressure: 8 kg/cm²) for 60 minutes, to give a copper-clad laminate for printed circuit board. Then, a circuit pattern was formed on the surface of the copper-clad laminate by leaving circuit pattern-forming regions and removing the other regions thereof by etching, and thereby a printed circuit board carrying a circuit on the surface was obtained.

The copper-clad laminates and the printed circuit boards for Examples 2 to 7 and Comparative Example 1 were respectively obtained in the same way as the above-mentioned method for producing the copper-clad laminate and the printed circuit board of Example 1.

The properties of the copper-clad laminates obtained in Examples 1 to 7 and Comparative Example 1 were respectively determined by the following evaluation tests.

### [Water Absorption]

The standard pressure cooker test (PCT) was done at 121° C., 100% relative humidity, and 2 atmospheric pressures for 1 hour.

### [Solder Floating]

The sample was kept floating on a solder bath of 288° C. for the time indicated in Table 1, and blister of the sample was visually observed.

### [Peeling Strength of Copper Foil]

A 1 oz of copper foil on the copper-clad laminate was peeled off for determination of its 90° peel strength (JIS-C-6481).

### [Glass Transition Temperature]

The glass transition temperature (Tg) was measured as peak temperature of tan δ at 1 Hz by a dynamic mechanical analyzer manufactured by Seiko Instruments, Inc.

### [Thermal Decomposition Temperature]

A resin was separated from a copper-clad laminate and analyzed in a thermogravimetric and differential thermal analyzer (TG-DTA). The programmed heating rate was 5° C./minute. The thermal decomposition temperature was the temperature at which the weight of the sample decreased by 5% from the initial weight.

### [Flame Retardancy]

The flame retardancy of a copper-clad laminate was evaluated by the method specified in UL 94. The UL 94 is a vertical burn test that classifies materials as V-0, V-1 or V-2.

### [Breaking Tenacity]

The laminate was set on a flat stage of the analyzer, and a vertical force was exerted on the laminate with a cross-shaped metal tool directly contacting the surface of the laminate for 1 minute, which left a cross-shaped mark on the surface of the laminate. Breaking tenacity was evaluated by visually observing the cross-shaped mark on the surface of the laminate as follows: good: no white crease; normal: occurrence of slightly white crease; and bad: occurrence of cracking or breakage.

### [Dielectric Properties]

The dielectric constant and the dissipation factor at 1 GHz were measured according to the procedures of ASTM D150-87.

The epoxy resin compositions and the test results of the test items above are summarized in Table 1.

TABLE 1
Epoxy Resin Compositions

| Relative to 100 parts by weight of | | | | | | | | | Comparative |
|---|---|---|---|---|---|---|---|---|---|
| the total weight of the epoxy resin. | | Example 1 | Example 2 | Example 3 | Example 4 | Example 5 | Example 6 | Example 7 | Example 1 |
| Epoxy resin | dicyclopentadiene | 100 | 100 | 100 | 80 | 100 | 100 | 70 | 100 |
| | type epoxy resin | | | | | | | | |
| | bisphenol A novolac | — | — | — | 20 | — | — | 30 | — |
| | epoxy resin | | | | | | | | |
| Curing agent | SMA | 40 | 30 | 80 | 40 | 40 | 40 | 30 | 40 |
| Curing | tetrabutylphosphonium | 0.5 | 0.5 | 0.5 | 0.5 | 0.5 | 0.5 | 0.5 | 0.5 |
| accelerator | acetate | | | | | | | | |
| Dispersing | silane dispersing agent | 0.5 | 0.5 | 0.5 | 0.5 | 0.5 | — | 0.5 | 0.5 |
| agent | | | | | | | | | |
| Flame | polyphosphazenes | 22 | 22 | 22 | 22 | — | 22 | 22 | 22 |
| retardant | DOPO-BNE | 15 | 15 | 15 | 15 | — | 15 | 15 | 15 |
| Toughening | carboxyl-terminated | 2 | 2 | 2 | 2 | 2 | 2 | — | — |
| agent | butadiene | | | | | | | | |
| | acrylonitrile rubber | | | | | | | | |
| Inorganic filler | talc | 60 | 60 | 60 | 60 | 60 | — | 60 | 60 |
| Solvent | MEK | 80 | 80 | 80 | 80 | 80 | 80 | 80 | 80 |

Test Results

| | | | | | | | | | | Comparative |
|---|---|---|---|---|---|---|---|---|---|---|
| Properties | Conditions | Unit | Example 1 | Example 2 | Example 3 | Example 4 | Example 5 | Example 6 | Example 7 | Example 1 |
| Water | PCT | % | 0.23 | 0.22 | 0.26 | 0.25 | 0.19 | 0.23 | 0.26 | 0.27 |
| absorption | 121° C., 1 hr. | | | | | | | | | |
| Solder floating | 288° C. | min | >30 | >30 | >30 | >30 | >30 | >30 | >30 | >30 |
| Peeling | | lb/in | 8.3 | 8.4 | 7.9 | 8.5 | 8.4 | 8.1 | 8.6 | 8.0 |
| strength (1 oz) | | | | | | | | | | |
| Glass | DMA | ° C. | 178.5 | 165.4 | 180.4 | 185.3 | 175.4 | 178.7 | 187.8 | 181.2 |
| transition | | | | | | | | | | |
| temperature | | | | | | | | | | |
| Thermal | TGA | ° C. | 378.9 | 365.4 | 380.1 | 382.5 | 335.1 | 334.9 | 389.8 | 374.6 |
| decomposition | | | | | | | | | | |
| temperature | | | | | | | | | | |
| Flame | rating | UL94 | V-0 | V-0 | V-1 | V-0 | V-1 | V-0 | V-1 | V-0 |
| retardancy | | | | | | | | | | |
| Breaking | | | Good | Good | Normal | Good | Good | Good | Normal | Bad |
| tenacity | | | | | | | | | | |
| Dielectric | Dk at 1 GHz | | 4.25 | 4.35 | 4.18 | 4.45 | 4.39 | 4.37 | 4.46 | 4.31 |
| constant | | | | | | | | | | |
| Dissipation | Df at 1 GHz | | 0.008 | 0.011 | 0.007 | 0.012 | 0.014 | 0.012 | 0.014 | 0.09 |
| factor | | | | | | | | | | |

As seen from Table 1, the copper-clad laminates obtained according to the present invention (Examples 1 to 7) have the well-balanced properties and every required performance for use as printed circuit boards. These copper-clad laminates are excellent in heat resistance, breaking tenacity, and dielectric properties, and especially in Examples 1, 3, 4, and 7, the copper-clad laminates have relatively high glass transition temperatures (Tg) and thermal decomposition temperature. In some cases, the dicyclopentadiene type epoxy resin is blended with the bisphenol type epoxy resin, as shown in Examples 4 and 7 (with the improvement of glass transition temperature and meanwhile, the increase of dielectric constant and the dissipation factor). Furthermore, it is worthy of note that the glass transition temperature (Tg), the thermal decomposition temperature, the dielectric constant, and the dissipation factor are correlated to the blend proportion of a dicyclopentadiene type epoxy resin and a copolymer of styrene and maleic anhydride according to Examples 1 to 3, and Example 1 is the preferred embodiment of the present invention. Furthermore, although no inorganic filler was used in the epoxy resin composition in the case of Example 6, the copper-clad laminate obtained according to Example 6 still has the required performance for use as printed circuit boards. Furthermore, as compared with Examples 1 of the present invention, the copper-clad laminate of Comparative Example 1 has poor breaking tenacity (resulting in the increase of brittleness) and relatively high dissipation factor.

Thus, the copper-clad laminates or the printed circuit boards of the present invention can be used with high reliability. Accordingly, the copper-clad laminates or the printed circuit boards of the present invention prepared from the epoxy resin composition, which comprises a dicyclopentadiene type epoxy resin and a copolymer of styrene and maleic anhydride blended in a certain proportion, exhibit low dielectric characteristics along with improved glass transition temperature, heat resistance, breaking tenacity and processibility, and at the meanwhile, the problem of brittleness, which occurs when a copolymer of styrene and maleic anhydride was used as epoxy cross-linking agent, can be prevented.

It is contemplated that various modifications may be made to the compositions, prepregs, laminates and printed circuit boards of the present invention without departing from the spirit and scope of the invention as defined in the following claims.

What is claimed is:

1. A prepreg produced by impregnating a reinforcing material with an epoxy resin composition to form an impregnated substrate, and drying the impregnated substrate to a semi-cured state, wherein the epoxy resin composition, comprising:
(A) an epoxy resin comprising a dicyclopentadiene type epoxy resin represented by the following general formula (I): 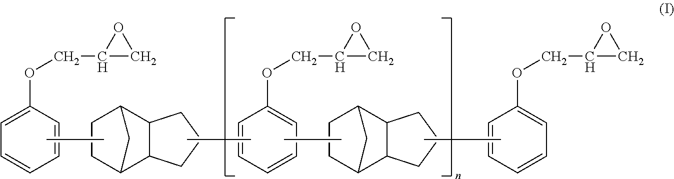
wherein n is an integer of 0 to 10; and
(B) 30 to 80 parts by weight of a copolymer of styrene and maleic anhydride as a curing agent, based on 100 parts by weight of the epoxy resin, the copolymer of styrene and maleic anhydride being represented by the following general formula (II): 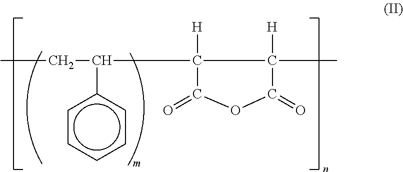
wherein m is an integer of 1 to 6, and n is an integer of 2 to 12.

2. A printed circuit board produced by laminating a particular number of the prepregs according to claim 1 to form a prepreg laminate, placing a metal foil on at least one outermost layer of the prepreg laminate and heat pressure-molding the prepreg laminate to form a metal-clad laminate, and forming a circuit pattern on a surface of the metal foil on the metal-clad laminate.
